(19) United States
(12) Patent Application Publication
(10) Pub. No.: US 2025/0196199 A1
(43) Pub. Date: Jun. 19, 2025

(54) ELECTRONIC COMPONENT CLEANING METHOD

(71) Applicants: YAMAHA ROBOTICS HOLDINGS CO., LTD., Tokyo (JP); KURITA WATER INDUSTRIES LTD., Tokyo (JP)

(72) Inventors: HIROSHI KIKUCHI, Tokyo (JP); JIN LI, Tokyo (JP); Junichi IDA, Tokyo (JP)

(73) Assignees: YAMAHA ROBOTICS HOLDINGS CO., LTD., Tokyo (JP); KURITA WATER INDUSTRIES LTD., Tokyo (JP)

(21) Appl. No.: 18/843,320

(22) PCT Filed: Mar. 30, 2022
(86) PCT No.: PCT/JP2022/016130

§ 371 Date: Sep. 3, 2024

(51) Int. Cl. B08B 3/12; B08B 7/00; B08B 7/02; H01L 21/02

(52) U.S. Cl. CPC B08B 3/12; B08B 7/0035; B08B 7/028; H01L 21/02054

(57) ABSTRACT

An electronic component cleaning method for performing cleaning on a surface of a wafer includes: a wet cleaning process of performing wet cleaning on the surface of the wafer by hydrogen water and pure water; a dry cleaning process of performing dry cleaning on the surface of an electronic component by atmospheric-pressure plasma after the wet cleaning; and a hydrogen water treatment process of performing cleaning on the surface of the wafer using hydrogen water obtained by dissolving hydrogen gas into water, after the dry cleaning process.

### TECHNICAL FIELD

The present disclosure relates to a method for performing cleaning on a surface of an electronic component such as a wafer, a semiconductor chip, and a substrate.

### RELATED ART

When manufacturing a semiconductor device by bonding, it is required to clean a surface of a wafer such as a silicon wafer or a compound semiconductor wafer. Patent Document 1 discloses a bonding system in which, when performing bonding of two wafers, a surface of the wafer is scrubbed by a cleaning apparatus, surface modification is performed on the wafer by a plasma treatment, the surface of the wafer is hydrophilized by pure water, and then bonding is performed.

### RELATED ART DOCUMENTS

### Patent Documents

Patent Document 1: Japanese Patent Application Laid-Open No. 2020-155759

### SUMMARY OF INVENTION

### Problem to be Solved by Invention

However, as in the conventional art described in Patent Document 1, in the case of performing a hydrophilization treatment on the surface of the wafer by pure water after performing a modification treatment on the surface by plasma, a hydrophilicity of the surface may decrease over time, and a bonding quality may deteriorate.

Thus, an objective of the present disclosure is to maintain a high hydrophilicity of a surface of an electronic component.

### Means for Solving Problem

An electronic component cleaning method of the present disclosure is an electronic component cleaning method for performing cleaning on a surface of an electronic component, and includes: a wet cleaning process of performing wet cleaning on the surface of the electronic component by a liquid; a dry cleaning process of performing dry cleaning on the surface of the electronic component by atmospheric-pressure plasma after the wet cleaning; and a hydrogen water treatment process of performing hydrophilization on the surface of the electronic component using hydrogen water obtained by dissolving hydrogen gas into water, after the dry cleaning process.

By performing a hydrogen water treatment after the dry cleaning by atmospheric-pressure plasma in this manner, a high hydrophilicity of the surface of the electronic component can be maintained, and a bonding quality can be improved.

In the electronic component cleaning method of the present disclosure, the hydrogen water treatment process may be started immediately after an end of the dry cleaning process. Herein, the hydrogen water treatment process may be started within 30 seconds after the end of the dry cleaning process, or the hydrogen water treatment process may be started within 10 seconds after the end of the dry cleaning process.

Accordingly, a high hydrophilicity of the surface of the electronic component can be maintained for a longer period of time.

In the electronic component cleaning method of the present disclosure, the hydrogen water treatment process may include spraying the hydrogen water, which is ultrasonically vibrated, to the surface of the electronic component.

Accordingly, the hydrophilicity of the surface of the electronic component can be increased.

In the electronic component cleaning method of the present disclosure, the electronic component may be a wafer, a semiconductor chip, or a substrate for a semiconductor device. Herein, the semiconductor chip may be adhered onto a support material.

### Effect of Invention

The present disclosure can maintain a high hydrophilicity of a surface of an electronic component.

### BRIEF DESCRIPTION OF DRAWINGS

FIG. 1 is a plan view of a first floor of an electronic component cleaning apparatus for executing an electronic component cleaning method of an embodiment.

FIG. 2 is a plan view of a second floor of the electronic component cleaning apparatus shown in FIG. 1.

FIG. 3 is a vertical cross-sectional view of a wet cleaning unit and a dry cleaning unit of the electronic component cleaning apparatus shown in FIG. 1.

FIG. 4 is a system view showing a control system of the electronic component cleaning apparatus shown in FIG. 1.

FIG. 5 is a flowchart showing actions of the electronic component cleaning apparatus shown in FIG. 1 executing the electronic component cleaning method of the embodiment.

FIG. 6 is a view showing an action of the electronic component cleaning apparatus shown in FIG. 3 executing the electronic component cleaning method of the embodiment, and is a vertical cross-sectional view showing a state in which a wafer is held on a treatment stage.

FIG. 7 is a view showing an action of the electronic component cleaning apparatus shown in FIG. 3 executing the electronic component cleaning method of the embodiment, and is a vertical cross-sectional view during wet cleaning.

FIG. 8 is a view showing an action of the electronic component cleaning apparatus shown in FIG. 3 executing the electronic component cleaning method of the embodiment, and is a vertical cross-sectional view showing a state in which the wafer is moved from a wet cleaning chamber to a dry cleaning chamber.

FIG. 9 is a view showing an action of the electronic component cleaning apparatus shown in FIG. 3 executing the electronic component cleaning method of the embodiment, and is a vertical cross-sectional view during dry cleaning.

FIG. 10 is a view showing an action of the electronic component cleaning apparatus shown in FIG. 3 executing the electronic component cleaning method of the embodiment, and is a cross-sectional view during a hydrogen water treatment.

FIG. 11 is a graph showing over-time changes in a pure water contact angle and a hydrophilicity after an end of the dry cleaning by atmospheric-pressure plasma, and over-time changes in the pure water contact angle and the hydrophilicity after a hydrogen water treatment when the hydrogen water treatment is performed after the dry cleaning by atmospheric-pressure plasma.

FIG. 12 is a vertical cross-sectional view of an electronic component cleaning apparatus of another embodiment executing the electronic component cleaning method of the embodiment.

FIG. 13 is a system view showing a control system of the electronic component cleaning apparatus shown in FIG. 12.

FIG. 14 is a flowchart showing actions of the electronic component cleaning apparatus shown in FIG. 12 executing an electronic component cleaning method of another embodiment.

FIG. 15 is a cross-sectional view showing a semiconductor chip adhered onto a dicing film and a ring to which the dicing film is attached.

### DESCRIPTION OF EMBODIMENTS

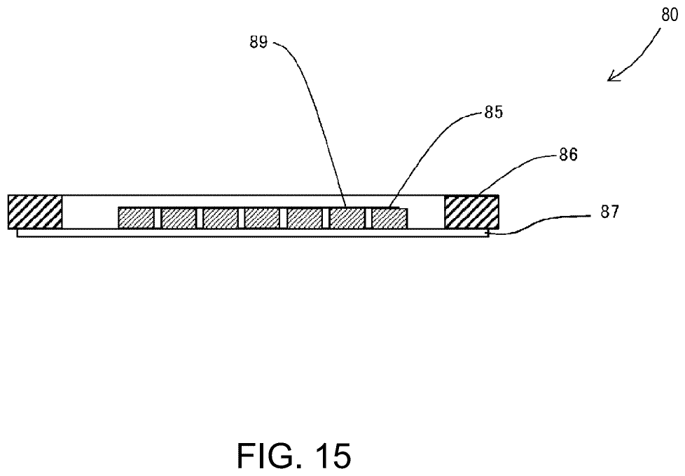

Hereinafter, an electronic component cleaning apparatus 100 executing an electronic component cleaning method of an embodiment will be described with reference to the drawings. In the following description, a case where the electronic component cleaning apparatus 100 performs cleaning on a surface 81 of a wafer 80, which is an electronic component, will be described. However, the electronic component cleaning apparatus 100 may also perform cleaning on a surface 89 (see FIG. 15) of a semiconductor chip 85, or may also clean a surface of a substrate for semiconductor devices to which the semiconductor chip 85 is bonded.

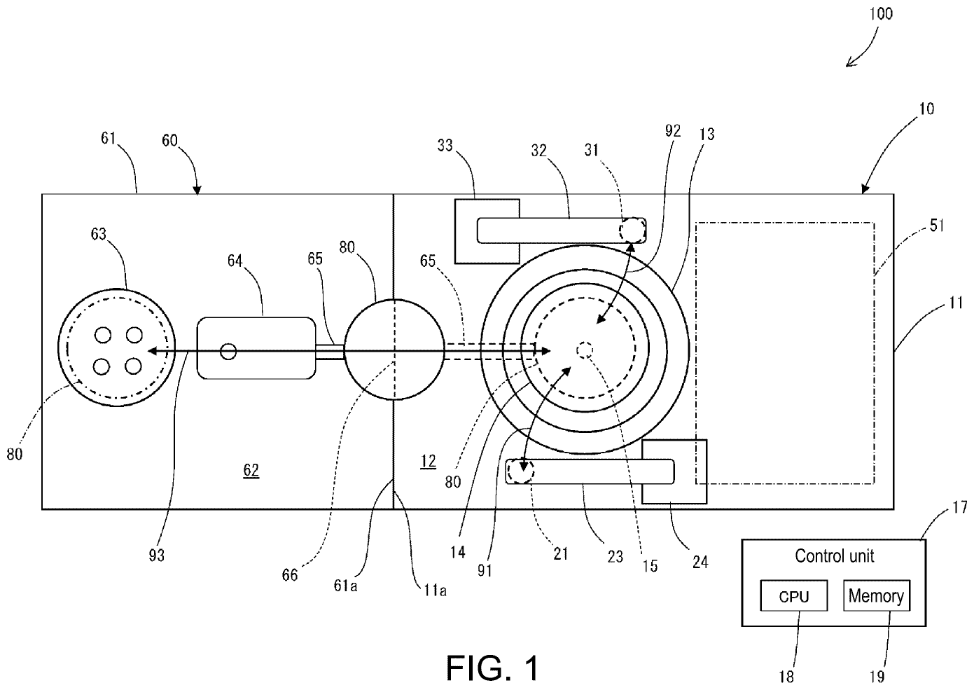

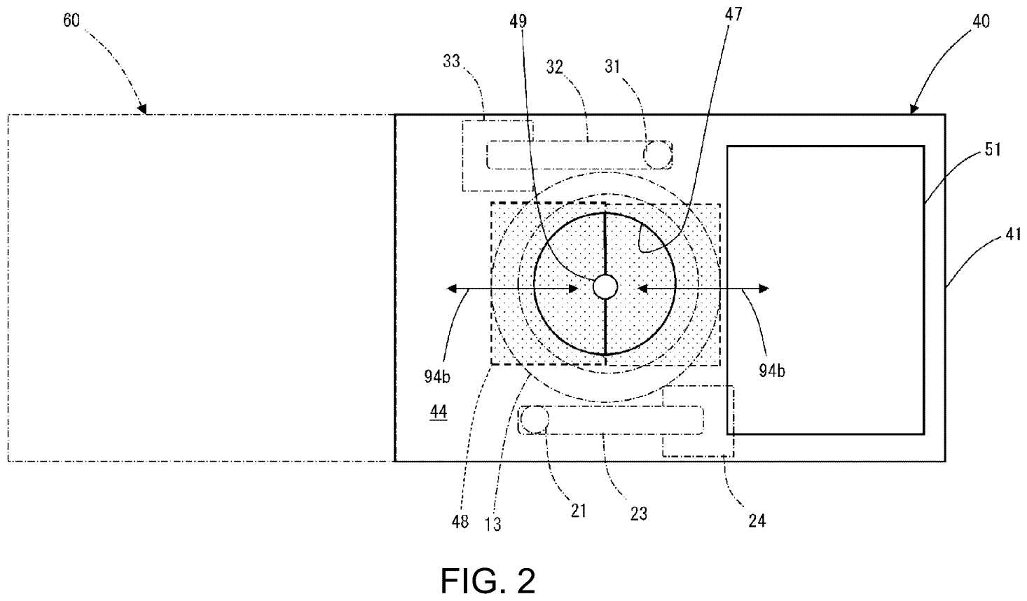

As shown in FIG. 1 and FIG. 2, the electronic component cleaning apparatus 100 has a two-floor structure including a first floor shown in FIG. 1 and a second floor shown in FIG. 2. As shown in FIG. 1, a wet cleaning unit 10 and a transverse transfer unit 60 are disposed adjacently on the first floor. Further, a control unit 17 is disposed on the first floor. On the second floor, a dry cleaning unit 40 is disposed overlapping above the wet cleaning unit 10.

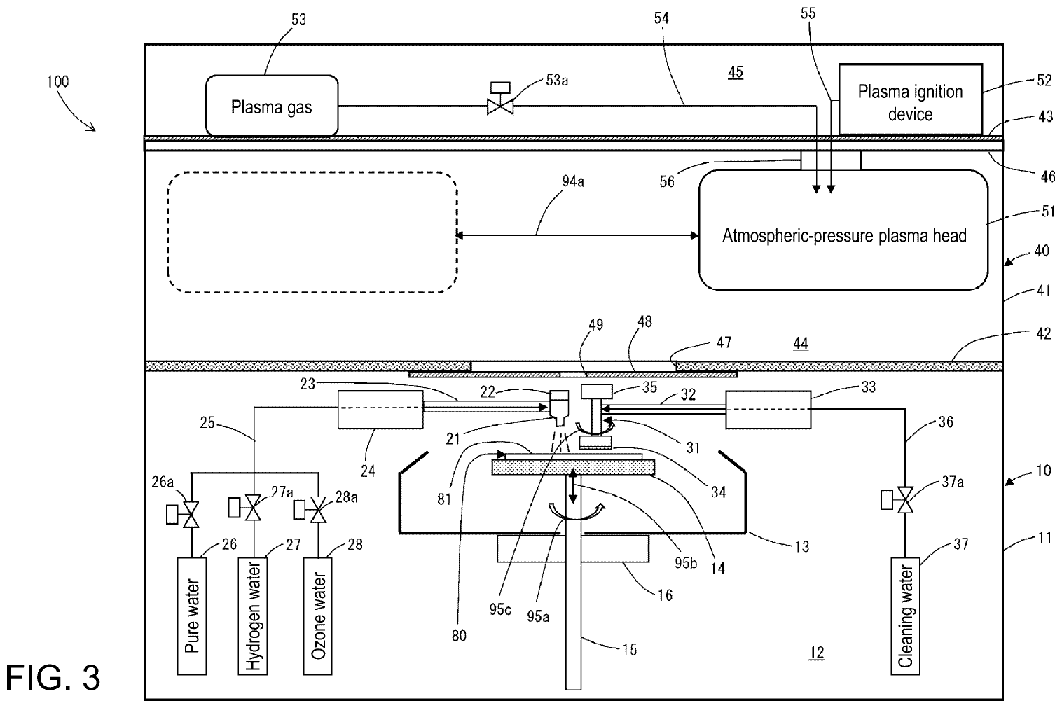

As shown in FIG. 1 and FIG. 3, the wet cleaning unit 10 includes: a substantially rectangular cuboidal casing 11; a wet cleaning chamber 13 disposed at an inside 12 of the casing 11; a treatment stage 14; a stage driving device 16 driving the treatment stage 14; a water nozzle 21; an ultrasonic vibrator 22; a nozzle arm 23; a nozzle arm driving part 24; a wiping head 31; a head arm 32; a head arm driving part 33; a rotational pressing driving part 35; a wiping member 34; a pure water tank 26; a hydrogen water tank 27; an ozone water tank 28; and a cleaning water tank 37.

The treatment stage 14 is a disc-shaped member that holds a wafer 80 on an upper surface. A shaft 15 is connected to a lower side of the treatment stage 14. The shaft 15 is rotationally driven by the stage driving device 16 as indicated by an arrow 95a in FIG. 3, and is driven in an up-down direction as indicated by an arrow 95b in FIG. 3. Accordingly, the treatment stage 14 is driven to rotate and move in the up-down direction by the stage driving device 16 while holding the wafer 80. As will be described later, the treatment stage 14 constitutes a transfer unit that transfers the wafer 80 in the up-down direction between the wet cleaning chamber 13 of the wet cleaning unit 10 and a dry cleaning chamber 44 of the dry cleaning unit 40 when a shutter 48 is opened.

The water nozzle 21 is disposed above the treatment stage 14 and sprays pure water, ozone water, and hydrogen water to the wafer 80 held on the upper surface of the treatment stage 14. The water nozzle 21 is attached to a tip of the nozzle arm 23. A base of the nozzle arm 23 is connected to the nozzle arm driving part 24. The nozzle arm driving part 24 rotates and moves the nozzle arm 23 within a plane as indicated by an arrow 91 in FIG. 1 to insert and retract the water nozzle 21, which is attached to the tip of the nozzle arm 23, with respect to the upper surface of the treatment stage 14. The ultrasonic vibrator 22, which imparts ultrasonic vibrations to pure water, hydrogen water, and ozone water sprayed from the water nozzle 21, is attached above the water nozzle 21.

The wiping head 31 is disposed on an upper side of the treatment stage 14, and

rotationally drives the wiping member 34 attached to a lower end as indicated by an arrow 95c in FIG. 3 by the rotational pressing driving part 35 attached to an upper end. Also, the wiping head 31 causes the wiping member 34 to contact the upper surface of the wafer 80 to wipe and clean the surface 81 of the wafer 80. The wiping member 34 may be a woven fabric or a knitted fabric using, for example, microfiber. Further, a cleaning water nozzle that sprays cleaning water to the wafer 80 is incorporated into the wiping head 31.

The wiping head 31 is attached to a tip of the head arm 32. A base of the head arm 32 is connected to the head arm driving part 33. The head arm driving part 33 rotates and moves the head arm 32 within a plane as indicated by an arrow 92 in FIG. 1 to insert and retract the wiping head 31, which is attached to the tip of the head arm 32, with respect to the upper surface of the treatment stage 14.

The wet cleaning chamber 13 is provided on a lower side of the treatment stage 14 and is a circular pan that receives pure water, ozone water, and hydrogen water sprayed from the water nozzle 21 or cleaning water sprayed from the wiping head 31. An opening of the wet cleaning chamber 13 narrows toward an upper part. The opening at the upper part has a size allowing placing and removal of the wafer 80.

The pure water tank 26, the hydrogen water tank 27, and the ozone water tank 28 are tanks that store pure water, hydrogen water, and ozone water, respectively. Herein, hydrogen water is water in which hydrogen gas is dissolved, and ozone water is water in which ozone gas is dissolved. Instead of the hydrogen water tank 27 and the ozone water tank 28, a hydrogen water generator that generates hydrogen water and an ozone water generator that generates ozone water may also be disposed. Further, the cleaning water tank 37 stores cleaning water such as pure water, hydrogen water, alkali-added hydrogen water, or carbonated water.

The pure water tank 26, the hydrogen water tank 27, and the ozone water tank 28 are connected to the water nozzle 21 respectively by a pure water valve 26a, a hydrogen water valve 27a, an ozone water valve 28a, and a piping 25. Further, the cleaning water tank 37 is connected to the wiping head 31 by a cleaning water valve 37a and a piping 36.

As shown in FIG. 1, the transverse transfer unit 60 is disposed adjacent to the wet cleaning unit 10 on the first floor. The transverse transfer unit 60 includes a casing 61, a wafer handover stage 63 disposed at an inside 62 of the casing 61, and a transverse transfer robot 64 serving as a transverse transfer device. The wafer handover stage 63 is a stage that receives an uncleaned wafer 80 from outside and hands over a cleaned wafer 80. An opening 66 for transferring the wafer 80 between the transverse transfer unit 60 and the wet cleaning unit 10 is provided at a sidewall 11a of the casing 11 of the wet cleaning unit 10 and a sidewall 61a of the transverse transfer unit 60. As indicated by an arrow 93 in FIG. 1, the transverse transfer robot 64 transfers the wafer 80 between the wafer handover stage 63 and the treatment stage 14 of the wet cleaning unit 10 via the opening 66.

As shown in FIG. 2 and FIG. 3, the dry cleaning unit 40 includes: a substantially rectangular cuboidal casing 41 that is disposed overlapping above the casing 11 of the wet cleaning unit 10; a floor plate 42; a ceiling plate 43; a ceiling rail 46; an atmospheric-pressure plasma head 51; a plasma ignition device 52; a plasma gas tank 53; and a plasma head driving part 56.

A space partitioned by walls of the casing 41, the floor plate 42, and the ceiling plate 43 constitutes a dry cleaning chamber 44 in which a dry cleaning treatment is performed by atmospheric-pressure plasma sprayed from the atmospheric-pressure plasma head 51. Further, a space on the upper side of the ceiling plate 43 constitutes an equipment arrangement space 45 into which atmospheric-pressure plasma does not enter.

The atmospheric-pressure plasma head 51 may be, for example, a device composed of a plurality of plasma generating devices disposed side by side, the plasma generating devices each including a ceramic tube through which a plasma gas flows, a negative electrode disposed on an outer side of the ceramic tube, and a grounded electrode disposed inside the ceramic tube, and applying a high voltage between the negative electrode and the grounded electrode to generate a discharge within the ceramic tube to eject plasma from a tip. The atmospheric-pressure plasma head 51 is attached to the ceiling rail 46 via the plasma head driving part 56. As indicated by an arrow 94a in FIG. 3, the plasma head driving part 56 reciprocatingly moves the atmospheric-pressure plasma head 51 in a horizontal direction.

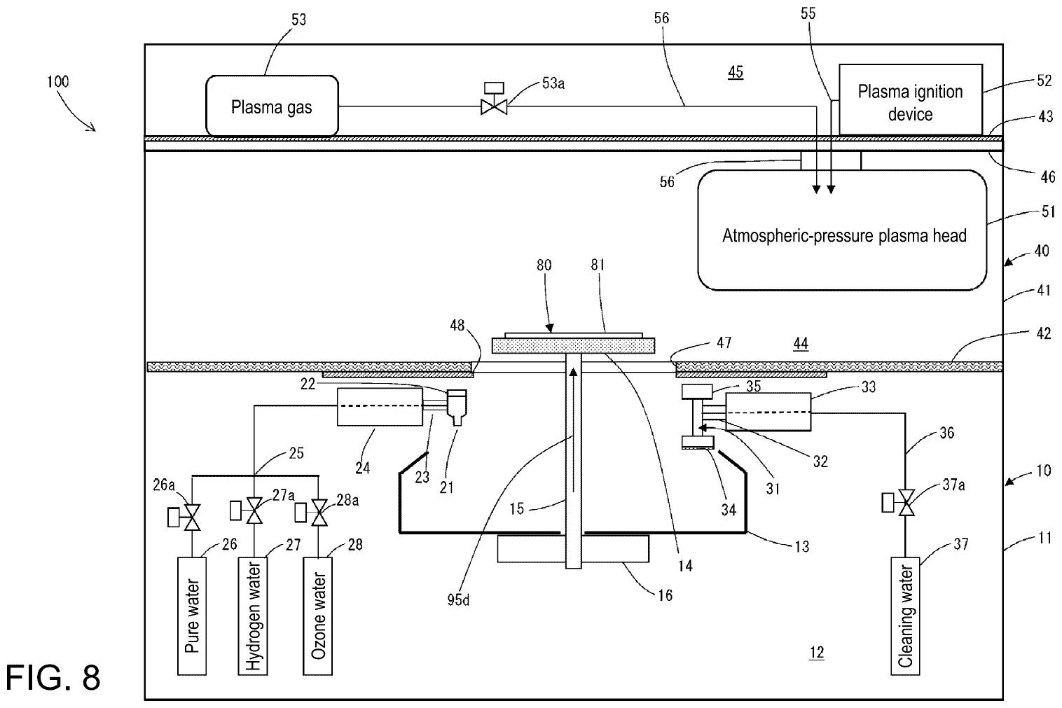

At a central part of the floor plate 42, an opening 47 through which the treatment stage 14 is movable in the up-down direction is provided on the upper side of the treatment stage 14 of the wet cleaning unit 10 disposed on the lower side. The shutter 48 which opens and closes the opening 47 is provided on the lower side of the floor plate 42. The shutter 48 slides as indicated by an arrow 94b in FIG. 2 by a driving part (not shown) to open and close the opening 47. Upon opening of the shutter 48, as shown in FIG. 8, the treatment stage 14 of the wet cleaning unit 10 is capable of moving upward as indicated by an arrow 95d to move from the wet cleaning chamber 13 into the dry cleaning chamber 44. The shutter 48 is closed after the treatment stage 14 is moved into the dry cleaning chamber 44. A semicircular notch 49 (see FIG. 2) is provided at a center of a joint surface of the two shutters 48 to form an opening through which the shaft 15 can penetrate between the wet cleaning unit 10 and the dry cleaning unit 40 at this time.

The plasma ignition device 52 is a device that supplies a high voltage to the electrodes disposed inside the atmospheric-pressure plasma head 51, and is connected to the atmospheric-pressure plasma head 51 by a connection line 55.

The plasma gas tank 53 is a tank that stores plasma gas. The plasma gas may be an inert gas such as argon or helium. The plasma gas tank 53 and the atmospheric-pressure plasma head 51 are connected to each other by a plasma gas valve 53a and a piping 54.

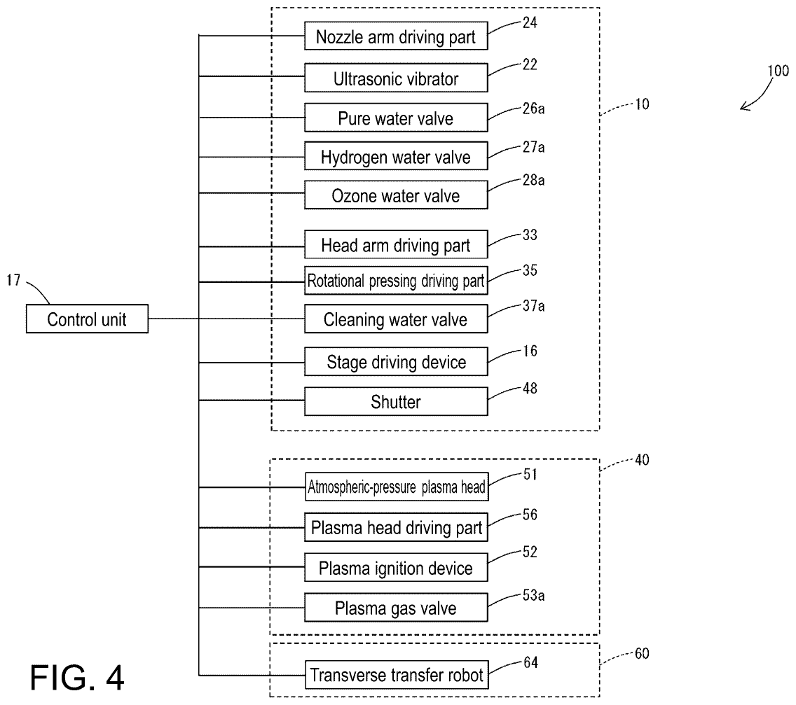

The control unit 17 is a computer including a CPU 18 and a memory 19 therein. As shown in FIG. 4, the control unit 17 is connected to the nozzle arm driving part 24, the ultrasonic vibrator 22, the pure water valve 26a, the hydrogen water valve 27a, the ozone water valve 28a, the head arm driving part 33, the rotational pressing driving part 35, the cleaning water valve 37a, the stage driving device 16, and the shutter 48 of the wet cleaning unit 10 to adjust actions of each device of the wet cleaning unit 10 and the treatment stage 14 constituting the transfer unit. Further, the control unit 17 is connected to the atmospheric-pressure plasma head 51, the plasma head driving part 56, the plasma ignition device 52, and the plasma gas valve 53a to adjust actions of each device of the dry cleaning unit 40. Furthermore, the control unit 17 is connected to the transverse transfer robot 64 of the transverse transfer unit 60 to adjust actions of the transverse transfer robot 64.

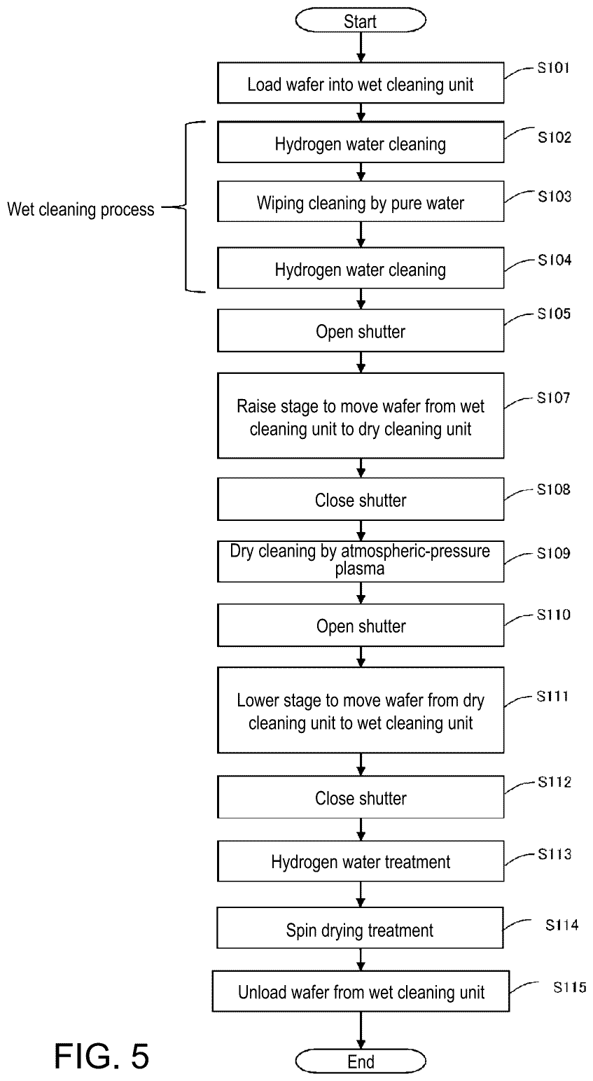

Next, referring to FIG. 5 to FIG. 10, actions of the electronic component cleaning apparatus 100 configured as described above executing the electronic component cleaning method of the embodiment to perform cleaning on a wafer 80 will be described.

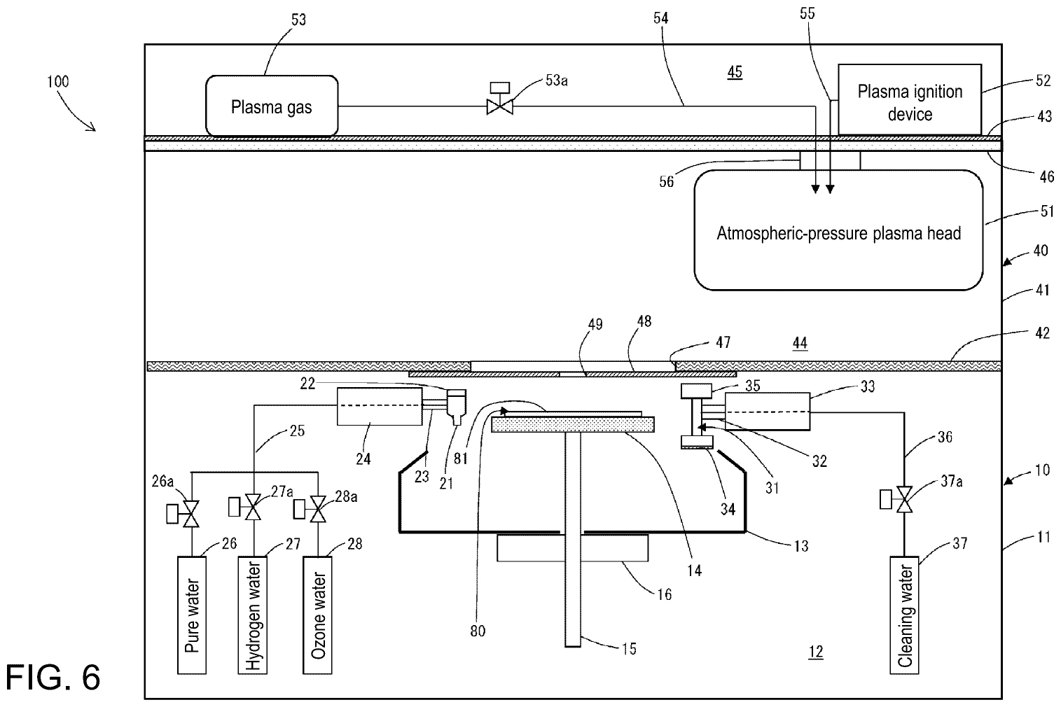

As shown in FIG. 6, in an initial state, the shutter 48 is closed, and the wet cleaning unit 10 and the dry cleaning unit 40 are partitioned by the floor plate 42 of the casing 41 of the dry cleaning unit 40 and the shutter 48. Further, as shown in FIG. 1, the nozzle arm 23 and the head arm 32 retract the water nozzle 21 and the wiping head 31 to positions that do not interfere with the treatment stage 14.

As indicated in step S101 of FIG. 5, the control unit 17 operates the transverse transfer robot 64 shown in FIG. 1 to pick up an uncleaned wafer 80 placed on the wafer handover stage 63, load the wafer 80 into the wet cleaning unit 10 as shown in FIG. 6, and place the wafer 80 on the treatment stage 14. The control unit 17 causes the wafer 80 to be held on the upper surface of the treatment stage 14.

In step S102 to step S104 of FIG. 5, the control unit 17 performs wet cleaning on the surface 81 of the wafer 80. Herein, step S102 to step S104 of FIG. 5 constitute a wet cleaning process. First, as shown in step S102 of FIG. 5, the control unit 17 executes hydrogen water cleaning.

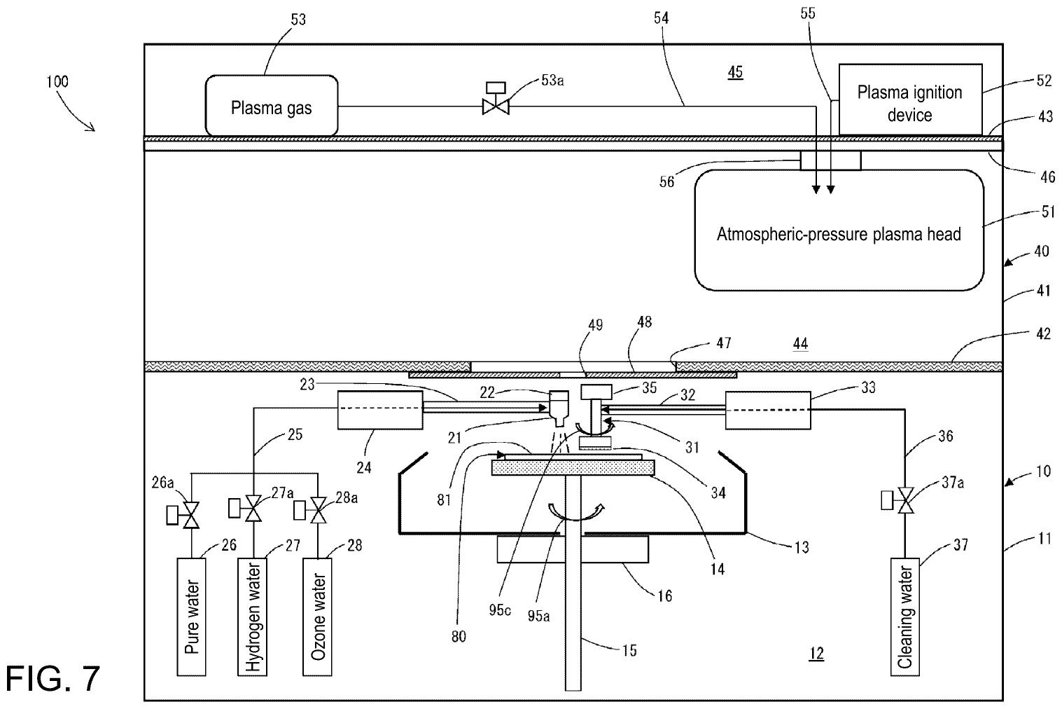

As shown in FIG. 7, the control unit 17 operates the nozzle arm driving part 24 to rotate the nozzle arm 23 and move the water nozzle 21 to above the treatment stage 14. Then, the control unit 17 rotates the treatment stage 14 by the stage driving device 16 and opens the hydrogen water valve 27a to spray hydrogen water from the water nozzle 21 toward the wafer 80 and perform cleaning on the wafer 80. At this time, the control unit 17 operates the ultrasonic vibrator 22 to apply ultrasonic vibrations to the hydrogen water, and sprays the ultrasonically vibrated hydrogen water to the surface of the wafer 80.

Next, the control unit 17 performs wiping cleaning by pure water in step S103 of FIG. 5. As shown in FIG. 7, the control unit 17 operates the head arm driving part 33 to rotate the head arm 32 and move the wiping head 31 to above the treatment stage 14. Since the water nozzle 21 has moved to above the treatment stage 14 during the above hydrogen water cleaning, the control unit 17 opens the pure water valve 26a to spray pure water from the water nozzle 21 toward the wafer 80, and operates the rotational pressing driving part 35 of the wiping head 31 to cause the wiping member 34 to contact the upper surface of the wafer 80 while rotationally driving the wiping member 34. The control unit 17 moves the wiping head 31 along the surface 81 of the wafer 80 by the head arm driving part 33 to wipe and clean the surface 81 of the wafer 80. At this time, the control unit 17 may open the cleaning water valve 37a to perform wiping cleaning on the surface 81 of the wafer 80 while causing cleaning water to be sprayed from the wiping head 31.

Next, in step S104 of FIG. 5, the control unit 17 again executes hydrogen water cleaning as in step S102 of FIG. 5.

With the wet cleaning in step S102 to step S104 of FIG. 5, inorganic and organic foreign substances are removed from the surface 81 of the wafer 80.

Upon ending of the wet cleaning, the control unit 17 transfers the wet-cleaned wafer 80 from the wet cleaning chamber 13 to the dry cleaning chamber 44 in step S105 to step S108 of FIG. 5.

In step S105 of FIG. 5, the control unit 17 opens the shutter 48. Further, the control unit 17 operates the nozzle arm driving part 24 and the head arm driving part 33 to retract the nozzle arm 23, the head arm 32, the water nozzle 21, and the wiping head 31 to positions that do not interfere with the treatment stage 14. Upon opening of the shutter 48 as shown in FIG. 8, in step S107 of FIG. 5 and in FIG. 8, the control unit 17 operates the stage driving device 16 to raise the treatment stage 14 as indicated by an arrow 95d in FIG. 8. Accordingly, the control unit 17 moves the treatment stage 14 from the wet cleaning chamber 13 into the dry cleaning chamber 44, and transfers the wafer 80 from the wet cleaning chamber 13 into the dry cleaning chamber 44. Then, upon moving the treatment stage 14 into the dry cleaning chamber 44, the control

unit 17 closes the shutter 48 in step S108 of FIG. 5.

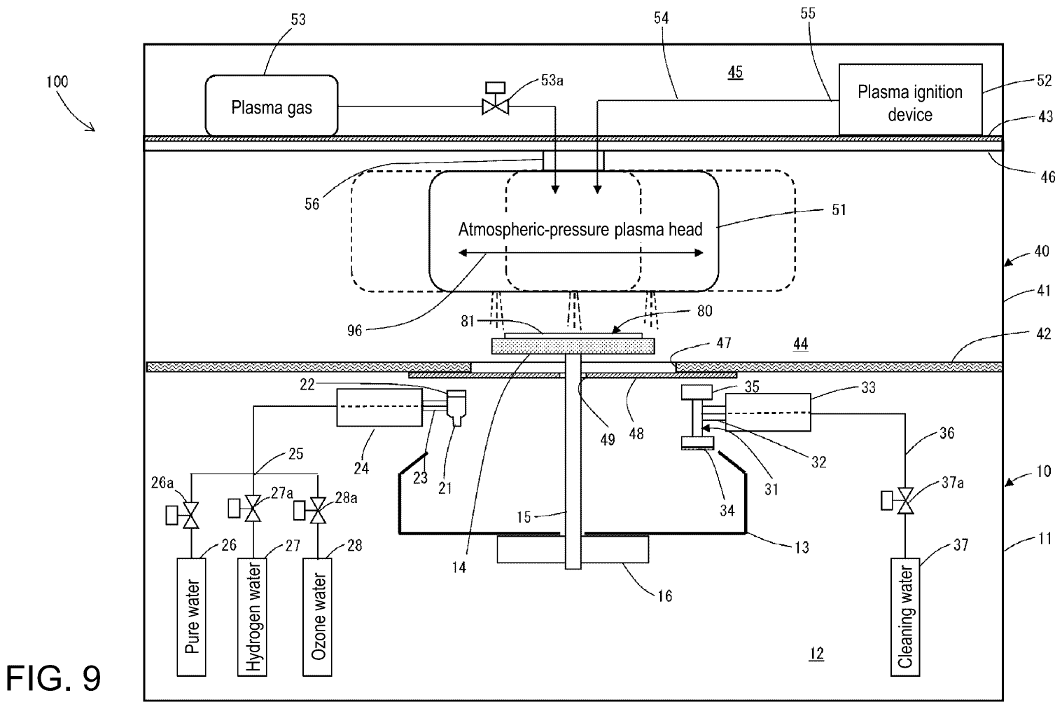

Next, the control unit 17 performs dry cleaning by atmospheric-pressure plasma in step S109 of FIG. 5. Herein, step S109 of FIG. 5 constitutes a dry cleaning process. The control unit 17 operates the plasma head driving part 56 to move the atmospheric-pressure plasma head 51 to above the treatment stage 14 as shown in FIG. 9. Then, the control unit 17 operates the plasma ignition device 52 to supply a high voltage from the plasma ignition device 52 to the atmospheric-pressure plasma head 51, and opens the plasma gas valve 53a to supply plasma gas from the plasma gas tank 53 to the atmospheric-pressure plasma head 51 to generate atmospheric-pressure plasma within the atmospheric-pressure plasma head 51. Then, as indicated by an arrow 96 in FIG. 9, the control unit 17 operates the plasma head driving part 56 to reciprocatingly move the atmospheric-pressure plasma head 51 above the wafer 80 and spray atmospheric-pressure plasma to the surface 81 of the wafer 80.

With the dry cleaning in step S109 of FIG. 5, the foreign substances adhering to the surface 81 of the wafer 80 are removed by irradiation of atmospheric-pressure plasma, and a hydrophilization treatment is performed on the surface of the wafer 80. Thus, after the dry cleaning, the surface 81 of the wafer 80 exhibits a high hydrophilicity.

Next, in step S110 to step S112 of FIG. 5, the control unit 17 transfers the dry-cleaned wafer 80 from the dry cleaning chamber 44 to the wet cleaning chamber 13. Similar to the description above, the control unit 17 opens the shutter 48 in step S110 of FIG. 5, operates the stage driving device 16 in step S111 of FIG. 5 to lower the treatment stage 14, and moves the treatment stage 14 from the dry cleaning chamber 44 into the wet cleaning chamber 13 to transfer the wafer 80 from the dry cleaning chamber 44 into the wet cleaning chamber 13. Then, the control unit 17 closes the shutter 48 in step S112 of FIG. 5.

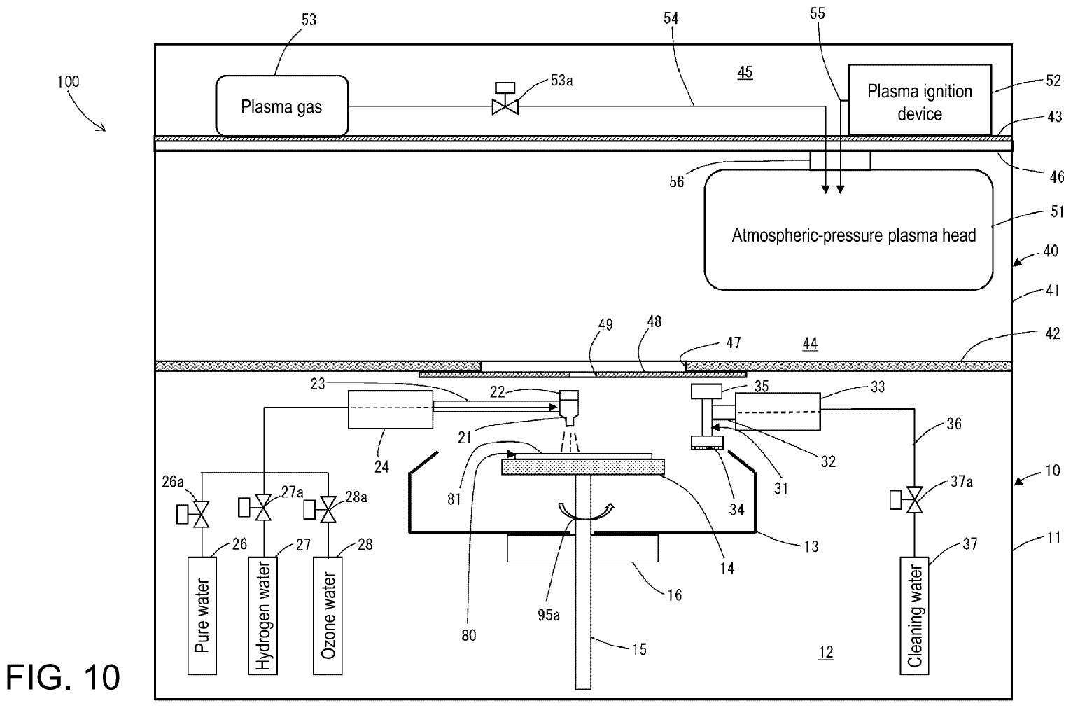

Next, proceeding to step S113 of FIG. 5, the control unit 17 performs hydrophilization on the surface 81 by a hydrogen water treatment. Herein, step S113 of FIG. 5 constitutes a hydrogen water treatment process. Similar to the hydrogen water cleaning described in step S102 of FIG. 5, as shown in FIG. 10, the nozzle arm driving part 24 is operated to rotate the nozzle arm 23 and move the water nozzle 21 to above the treatment stage 14, the treatment stage 14 is rotated by the stage driving device 16, and the hydrogen water valve 27a is opened to spray hydrogen water from the water nozzle 21 toward the wafer 80 to perform a hydrogen water treatment on the wafer 80. At this time, the control unit 17 operates the ultrasonic vibrator 22 to apply ultrasonic vibrations to the hydrogen water and sprays the ultrasonically vibrated hydrogen water to the surface of the wafer 80.

The hydrogen water treatment is a treatment similar to the hydrogen water cleaning in step S102 and step S104 of FIG. 5, but is intended to perform a hydrophilization treatment on the surface 81 rather than remove foreign substances from the surface 81 of the wafer 80. Thus, a treatment time is shorter than that of the hydrogen water cleaning in step S102 and step S104 of FIG. 5.

Upon ending of the hydrogen water treatment, proceeding to step S114 of FIG. 5, the control unit 17 performs a spin drying treatment. The control unit 17 rotates the treatment stage 14 at high speed by the stage driving device 16 to expel the hydrogen water remaining on the surface 81 of the wafer 80 to an outer circumferential side by a centrifugal force to dry the surface 81.

Upon ending of the spin drying treatment, proceeding to step S115 of FIG. 5, the control unit 17 unloads the wafer 80 from the wet cleaning unit 10. The control unit 17 operates the transverse transfer robot 64 shown in FIG. 1 to pick up the cleaned wafer 80 placed on the upper surface of the treatment stage 14, unload the wafer 80 from the wet cleaning unit 10, and place the wafer 80 onto the wafer handover stage 63 of the transverse transfer unit 60.

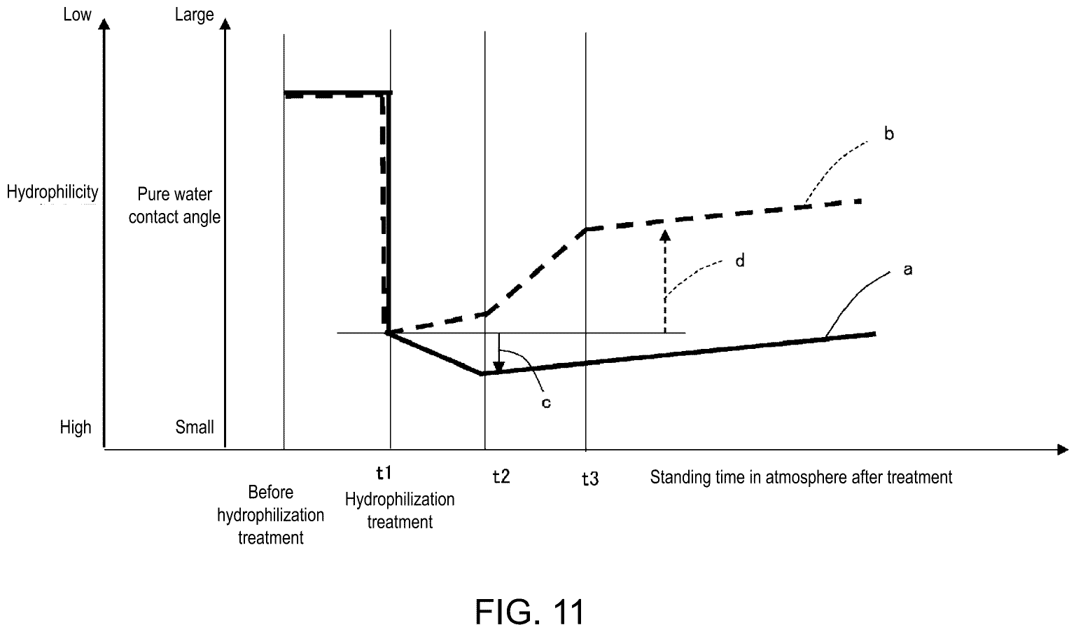

Next, with reference to FIG. 11, changes in hydrophilicity of the surface 81 of the wafer 80 will be described. A solid line a in FIG. 11 shows over-time changes in a pure water contact angle of the surface 81 in the case where hydrophilization by a hydrogen water treatment is performed immediately after dry cleaning by atmospheric-pressure plasma is executed, as in the cleaning action on the wafer 80 in the electronic component cleaning apparatus 100 of the embodiment described above. Further, a broken line b in FIG. 11 shows over-time changes in a pure water contact angle of the surface 81 in the case where only dry cleaning by atmospheric-pressure plasma is executed.

Herein, the pure water contact angle is an angle formed between the surface 81 and a liquid surface at a spot at which a free surface of stationary pure water contacts the surface 81. In the case where the pure water contact angle is large, hydrophilicity is low. In the case where the pure water contact angle is small, hydrophilicity is high.

First, changes in the pure water contact angle and the hydrophilicity of the surface 81 in the case where only dry cleaning by atmospheric-pressure plasma is executed will be described, as indicated by the broken line b in FIG. 11.

Upon execution of dry cleaning by atmospheric-pressure plasma at a time t1 in FIG. 11, foreign substances on the surface 81 are removed by irradiation of atmospheric-pressure plasma, the surface 81 is hydrophilized, and the pure water contact angle significantly decreases compared to before the dry cleaning. In other words, hydrophilicity increases. Upon leaving the wafer 80 in atmosphere after the dry cleaning by atmospheric-pressure plasma, the pure water contact angle gradually increases over time from the time t1, at which the dry cleaning ends, to a time t2. Then, after the time t2 and until a time t3, the pure water contact angle increases more significantly than between the time t1 and the time t2. Then, after the time t3, the pure water contact angle again gradually increases.

Thus, upon leaving the wafer 80 in atmosphere after executing the dry cleaning by atmospheric-pressure plasma, the pure water contact angle of the surface of the wafer 80 transitions to a higher state from the time t2 to the time t3 compared to the time of ending of the dry cleaning, as indicated by an arrow d in FIG. 11, and thereafter, the pure water contact angle gradually increases. In terms of changes in hydrophilicity, the hydrophilicity of the surface 81 of the wafer 80 transitions to a lower state from the time t2 to the time t3 compared to the time of ending of the hydrophilization, and thereafter, the hydrophilicity gradually decreases.

On the other hand, in the case of executing hydrophilization by a hydrogen water treatment immediately after dry cleaning by atmospheric-pressure plasma, as indicated by an arrow c in FIG. 11, from the time t1, at which the hydrogen water treatment ends, to the time t2, the pure water contact angle of the surface 81 gradually decreases even though the wafer 80 is left in atmosphere. After the time t2, the pure water contact angle of the surface 81 gradually increases. In terms of changes in hydrophilicity, from the time t1, at which the hydrogen water treatment ends, to the time t2, the hydrophilicity of the surface 81 gradually increases, and after the time t2, the hydrophilicity of the surface 81 gradually decreases.

Thus, in the case of executing hydrophilization by a hydrogen water treatment immediately after dry cleaning by atmospheric-pressure plasma, a hydrophilicity higher than the hydrophilicity at the end of the hydrogen water treatment can be maintained for a longer period of time.

Such an increase in hydrophilicity over time after the end of the hydrogen water treatment is believed to be due to attachment of hydroxyl groups to the surface 81 of the wafer 80 by the hydrogen water treatment. Herein, the inventors' research has shown that if the time from after the dry cleaning by atmospheric-pressure plasma to the start of the hydrogen water treatment is not short, the effect of increasing hydrophilicity over time as described above after the end of the hydrogen water treatment cannot be achieved.

Thus, in the electronic component cleaning apparatus 100 executing the electronic component cleaning method of the embodiment, the dry cleaning unit 40 is disposed overlapping above the wet cleaning unit 10, and the treatment stage 14 is moved up and down to transfer the wafer 80 between the dry cleaning unit 40 and the wet cleaning unit 10, to thereby shorten an interval between the dry cleaning process by atmospheric-pressure plasma and the hydrophilization by a hydrogen water treatment process. Accordingly, in the electronic component cleaning method of the embodiment, the hydrogen water treatment process can be started immediately after the end of the dry cleaning process by atmospheric-pressure plasma, more specifically, 5 to 10 seconds after the end of the dry cleaning process. Thus, the electronic component cleaning apparatus 100 of the embodiment can maintain a high hydrophilicity of the surface 81 of the wafer 80 over a long period of time, and can improve a bonding quality.

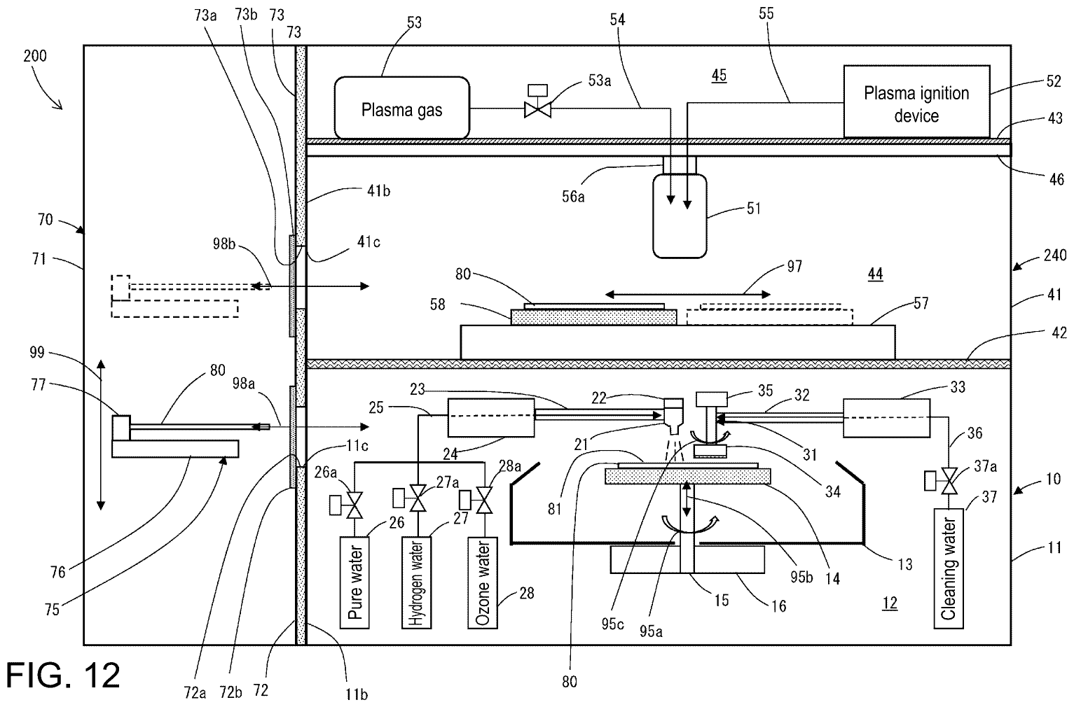

Next, an electronic component cleaning apparatus 200 executing the electronic component cleaning method of the embodiment will be described with reference to FIG. 12 to FIG. 14. Portions identical to those in the electronic component cleaning apparatus 100 described with reference to FIG. 1 to FIG. 11 above will be labeled with the same reference signs, and descriptions thereof will be omitted.

The electronic component cleaning apparatus 200 shown in FIG. 12 is obtained by disposing a vertical transfer unit 70 adjacent to sidewalls 11b and 41b of a wet cleaning unit 10 and a dry cleaning unit 240 disposed overlapping in an up-down direction. The vertical transfer unit 70 transfers a wafer 80 between a wet cleaning chamber 13 and a dry cleaning chamber 44. Further, although not shown in FIG. 12, the electronic component cleaning apparatus 200 includes a control unit 17.

The vertical transfer unit 70 includes a casing 71 and a vertical transfer device 75 disposed inside the casing 71.

The casing 71 is a substantially rectangular cuboidal member that is disposed adjacent to lateral surfaces of the wet cleaning unit 10 and the dry cleaning unit 240 and extends in the up-down direction across the wet cleaning unit 10 and the dry cleaning unit 240. An opening 72a. which communicates with an opening 11c of the sidewall 11b of the casing 11 of the wet cleaning unit 10, is provided at a first-floor sidewall 72 of the casing 71. Similarly, an opening 73a, which communicates with an opening 41c of the sidewall 41b of a casing 41 of the dry cleaning unit 240, is provided at a second-floor sidewall 73. Shutters 72b and 73b are respectively attached to the openings 72a and 73a.

The vertical transfer device 75 is disposed inside the casing 71, moves the wafer 80 in and out of the wet cleaning chamber 13 and the dry cleaning chamber 44, and transfers the wafer 80 between the wet cleaning chamber 13 and the dry cleaning chamber 44.

As shown in FIG. 12, the vertical transfer device 75 is composed of a main body 76 that moves in the up-down direction as indicated by an arrow 99 in FIG. 12, and a chuck 77 that is attached onto the main body 76 and slides in the horizontal direction. The chuck 77 grips the wafer 80 and reciprocatingly moves the wafer 80 in the horizontal direction as indicated by arrows 98a and 98b in FIG. 12.

The wet cleaning unit 10 has the same configuration as the wet cleaning unit 10 of the electronic component cleaning apparatus 100 described above with reference to FIG. 1 to FIG. 11. except that the opening 11c is provided at the sidewall 11b of the casing 11.

The dry cleaning unit 240 includes a treatment stage 58 that holds the wafer 80 inside the dry cleaning chamber 44, and a slide driving part 57 that reciprocatingly moves the treatment stage 58 in a direction indicated by an arrow 97 in FIG. 12. The atmospheric-pressure plasma head 51 is attached to the ceiling rail 46 by a bracket 56a and, different from the dry cleaning unit 40 described above with reference to FIG. 1 to FIG. 11, the atmospheric-pressure plasma head 51 does not move reciprocatingly. Further, the opening 41c is provided at the sidewall 41b of the casing 41.

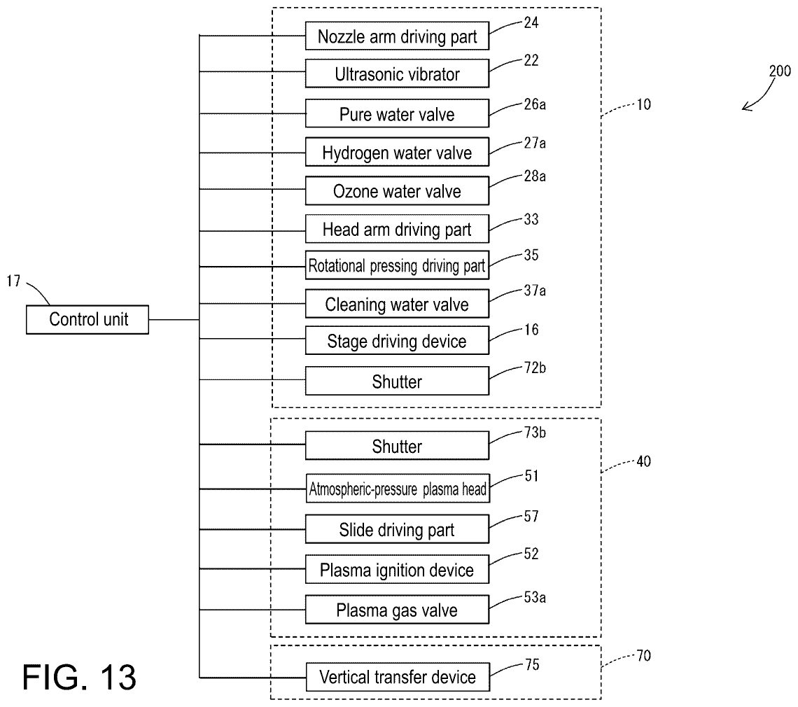

As shown in FIG. 13, in the electronic component cleaning apparatus 200, the control unit 17 is connected to the nozzle arm driving part 24, the ultrasonic vibrator 22, the pure water valve 26a, the hydrogen water valve 27a, the ozone water valve 28a, the head arm driving part 33, the rotational pressing driving part 35, the cleaning water valve 37a, the stage driving device 16, and the shutter 72b of the wet cleaning unit 10 to adjust actions of each device of the wet cleaning unit 10. Further, the control unit 17 is connected to the atmospheric-pressure plasma head 51. the slide driving part 57, the plasma ignition device 52, the plasma gas valve 53a, and the shutter 73b to adjust actions of each device of the dry cleaning unit 40. Furthermore, the control unit 17 is connected to the vertical transfer device 75 of the vertical transfer unit 70 to adjust actions of the vertical transfer device 75.

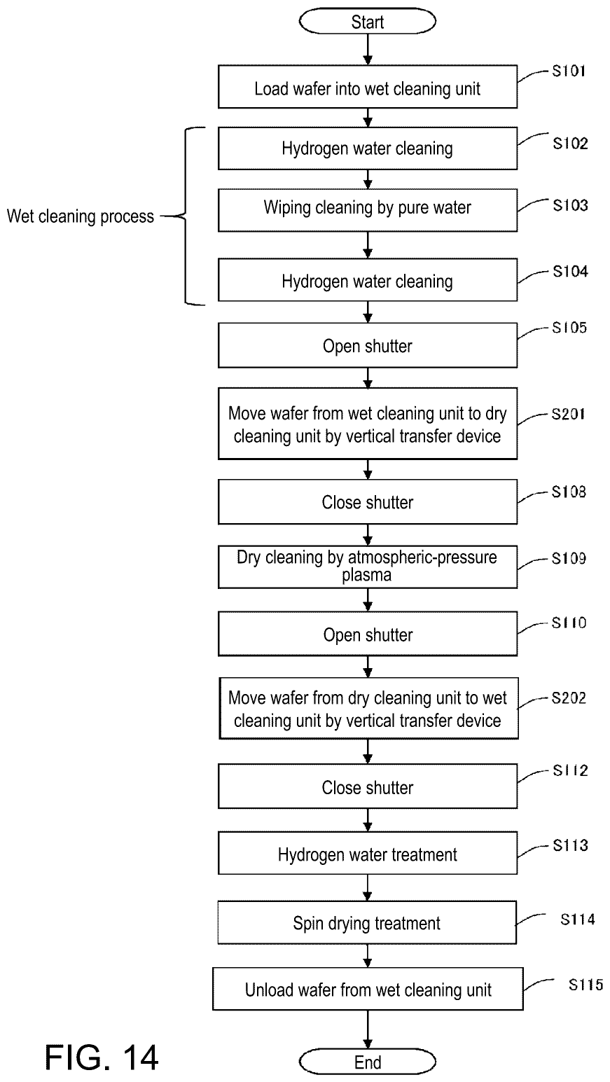

Next, with reference to FIG. 14, actions of the electronic component cleaning apparatus 200 configured as described above executing the electronic component cleaning method of the embodiment to perform cleaning on a wafer 80 will be described. Actions similar to those of the electronic component cleaning apparatus 100 described above with reference to FIG. 5 will be labeled with the same step numbers, and descriptions thereof will be omitted.

In step S101 of FIG. 14, the control unit 17 of the electronic component cleaning apparatus 200 operates the vertical transfer device 75 to load a wafer 80 into the wet cleaning unit 10, and similar to the electronic component cleaning apparatus 100, executes a wet cleaning process from step S102 to step S104 of FIG. 14.

Upon ending of the wet cleaning, the control unit 17 opens the shutters 72b and 73b in step S105 of FIG. 14, and operates the vertical transfer device 75 in step S201 of FIG. 14 to transfer the wafer 80 from the wet cleaning unit 10 to the dry cleaning unit 240. Then, upon ending of the transfer of the wafer 80, the control unit 17 closes the shutters 72b and 73b in step S108 of FIG. 14. Then, in step S109 of FIG. 14, the control unit 17 reciprocatingly moves the treatment stage 58, which holds the wafer 80 on an upper surface, by the slide driving part 57 to perform a dry cleaning process. Upon ending of the dry cleaning process, the control unit 17 opens the shutters 72b and 73b in step S110 of FIG. 14, and transfers the wafer 80 to the wet cleaning unit 10 by the vertical transfer device 75 in step S202 of FIG. 14. Then, the control unit 17 closes the shutters 72b and 73b in step S112 of FIG. 14 and proceeds to step S113 of FIG. 14 to perform a hydrogen water treatment process in the wet cleaning unit 10. Then, after performing a spin drying treatment process in step S114 of FIG. 14, the control unit 17 unloads the wafer 80 from the wet cleaning unit 10 by the vertical transfer device 75 in step S115 of FIG. 14.

Similar to the electronic component cleaning apparatus 100, since the electronic component cleaning apparatus 200 can start the hydrophilization by the hydrogen water treatment process immediately after the end of the dry cleaning process by atmospheric-pressure plasma, a high hydrophilicity of the surface 81 of the wafer 80 can be maintained, and a bonding quality can be improved.

In the above description, the electronic component cleaning apparatuses 100 and 200 have been described to execute the electronic component cleaning method of the embodiment to clean the surface 81 of the wafer 80, but the electronic component cleaning apparatuses 100 and 200 may also clean a surface of a semiconductor chip 85. As shown in FIG. 15, the semiconductor chip 85 is obtained by adhering a silicon dicing film 87, which serves as a support material, to a lower surface of a disc-shaped wafer 80, and forming slits and dividing in a grid pattern from an upper side by a dicing saw. Further, a ring 86 is attached to a surface on an upper side of an outer circumference of the dicing film 87. Thus, the semiconductor chip 85 is handled integrally with the ring 86 while being adhered to the upper surface of the dicing film 87. Reference sign “89” in FIG. 15 indicates a surface 89 of the semiconductor chip 85. The semiconductor chip 85 is not limited to being adhered onto the dicing film 87; but may also be adhered onto a silicon wafer, a glass plate, or a substrate.

Further, in the above description, the wet cleaning process has been described as being performed using hydrogen water, but is not limited thereto and may also be performed using ozone water. Further, in the hydrogen water cleaning process and the hydrogen water treatment process, hydrogen water may also be sprayed to the surface 81 of the wafer 80 without being ultrasonically vibrated.

### REFERENCE SIGNS LIST

10 Wet cleaning unit
11, 41, 61, 71 Casing
11a, 11b, 41b, 61a, 72, 73 Sidewall
11c, 41c, 47, 66, 72a, 73a Opening
12, 62 Inside
13 Wet cleaning chamber
14, 58 Treatment stage
15 Shaft
16 Stage driving device
17 Control unit
18 CPU
19 Memory
21 Water nozzle
22 Ultrasonic vibrator
23 Nozzle arm
24 Nozzle arm driving part
25, 36, 54 Piping
26 Pure water tank
26a Pure water valve
27 Hydrogen water tank
27a Hydrogen water valve
28 Ozone water tank
28a Ozone water valve
31 Wiping head
32 Head arm
33 Head arm driving part
34 Wiping member
35 Rotational pressing driving part
37 Cleaning water tank
37a Cleaning water valve
40, 240 Dry cleaning unit
42 Floor plate
43 Ceiling plate
44 Dry cleaning chamber
45 Equipment arrangement space
46 Ceiling rail
48, 72b, 73b Shutter
49 Notch
51 Atmospheric-pressure plasma head
52 Plasma ignition device
53 Plasma gas tank
53a Plasma gas valve
55 Connection line
56 Plasma head driving part
56a Bracket
57 Slide driving part
60 Transverse transfer unit
63 Wafer handover stage
64 Transverse transfer robot
70 Vertical transfer unit
75 Vertical transfer device
76 Main body
77 Chuck
5 80 Wafer
81, 89 Surface
85 Semiconductor chip
86 Ring
87 Dicing film
10 100, 200 Electronic component cleaning apparatus

1. An electronic component cleaning method for performing cleaning on a surface of an electronic component, the electronic component cleaning method comprising:
a wet cleaning process of performing wet cleaning on the surface of the electronic component by a liquid;
a dry cleaning process of performing dry cleaning on the surface of the electronic component by atmospheric-pressure plasma after the wet cleaning; and
a hydrogen water treatment process of performing a cleaning treatment on the surface of the electronic component using hydrogen water obtained by dissolving hydrogen gas into water, after the dry cleaning process.

2. The electronic component cleaning method according to claim 1, wherein
the hydrogen water treatment process is started immediately after an end of the dry cleaning process.

3. The electronic component cleaning method according to claim 2, wherein
the hydrogen water treatment process is started within 30 seconds after the end of the dry cleaning process.

4. The electronic component cleaning method according to claim 3, wherein
the hydrogen water treatment process is started within 10 seconds after the end of the dry cleaning process.

5. The electronic component cleaning method according to claim 1, wherein
the hydrogen water treatment process comprises spraying the hydrogen water, which is ultrasonically vibrated, to the surface of the electronic component.

6. The electronic component cleaning method according to claim 1, wherein
the electronic component is a wafer, a semiconductor chip, or a substrate for a semiconductor device.

7. The electronic component cleaning method according to claim 6, wherein
the semiconductor chip is adhered onto a support material.
